(19) United States
(12) Patent Application Publication
(10) Pub. No.: US 2026/0179663 A1
(43) Pub. Date: Jun. 25, 2026

(54) Memory with Enhanced Recovery from a Light-Sleep Mode

(71) Applicant: QUALCOMM Incorporated, San Diego, CA (US)

(72) Inventors: Sonia GHOSH, San Diego, CA (US); Xiao CHEN, San Diego, CA (US); Chi-Jui CHEN, San Diego, CA (US)

(21) Appl. No.: 18/991,227

(22) Filed: Dec. 20, 2024

(51) Int. Cl. G11C 5/14

(52) U.S. Cl. CPC G11C 5/148

(57) ABSTRACT

A circuit is provided with a first head switch transistor at one end of a plurality of columns of bitcells and a second head switch transistor at a second end of the plurality of columns. During a light-sleep mode, the first head switch transistor is diode connected so that a power supply voltage passing through the diode-connected first head switch transistor is reduced by a transistor threshold voltage drop. The second head switch transistor is off during the light-sleep mode During an active mode, the diode connection is opened so that the first head switch transistor passes a power supply voltage with virtually no voltage drop. The second head switch transistor is on only during a transition period from the light-sleep mode to the active mode.

### TECHNICAL FIELD

This application relates to integrated circuits, and more particularly to an integrated circuit embedded memory with enhanced recovery from a light-sleep mode.

### BACKGROUND

An integrated circuit embedded memory will typically have various operating modes in which a memory power supply voltage for the embedded memory is varied according to the operating mode. In a default mode (which may also be denoted as a normal mode), the memory power supply voltage is sufficiently elevated for increased memory speed. In contrast, the memory power supply voltage is decreased from the default level for a light-sleep mode or even discharged to ground during a deep-sleep mode. For example, during the deep-sleep mode, head switch transistors that intervene between a memory power supply voltage rail and the memory are switched off so that the memory is powered down. In the light-sleep mode, the head switch transistors may also be switched off so that the memory may be powered through diode-connected transistors that couple between the memory power supply voltage rail and the memory. The diode-connected transistors lower the memory power supply voltage by a threshold voltage drop. In this fashion, leakage currents are reduced during the light-sleep mode due to the reduced memory power supply voltage, yet the memory may retain its binary contents and also revert back to the active mode relatively quickly.

### SUMMARY

In accordance with an aspect of the disclosure, a memory is provided that includes: a plurality of bitcells arranged into a plurality of columns, each column being traversed by at least one power rail extending from a first node at a first end of the column to a second node at a second end of the column; a power supply node for a memory power supply voltage; an at least one first head switch transistor having a first terminal coupled to the power supply node and a second terminal coupled to the first node; a second transistor having a first terminal coupled to a gate of the at least one first head switch transistor and having a second terminal coupled to the first node; and an at least one second head switch transistor having a first terminal coupled to the power supply node and a second terminal coupled to the second node.

In accordance with another aspect of the disclosure, a method of powering a memory is provided that includes the acts of: switching on a diode-connecting transistor that couples between a gate and a drain of an at least one first head switch transistor to diode connect the at least one first head switch transistor during a light-sleep mode for the memory; powering a first end of a power rail at a first end of a column of bitcells in the memory through the at least one first head switch transistor while the diode-connecting transistor is switched on during the light-sleep mode for the circuit and while an at least one second head switch transistor that is coupled to a second end of the power rail at a second end of the column of bitcells is off; switching off the diode-connecting transistor to return the at least one first head switch transistor to a non-diode-connected state during a transition period from the light-sleep mode to an active mode for the memory; switching on the at least one second head switch transistor during the transition period; and switching off the at least one second head switch transistor at a termination of the transition period while maintaining the at least one first head switch transistor on.

In accordance with yet another aspect of the disclosure, a memory is provided that includes: a power supply node for a memory power supply voltage; a column of bitcells; a power rail extending from a first end of the power rail at a first end of the column of bitcells to a second end of the power rail at a second end of the column of bitcells; an at least one first head switch transistor coupled between the power supply node and the first end of the power rail; an at least one second head switch transistor coupled between the power supply node and the second end of the power rail; and a memory controller configured to control the at least one first head switch transistor to be diode-connected state during a light-sleep mode for the memory and to be in a non-diode-connected state during an active mode for the memory, wherein the memory controller is further configured to control the at least one second head switch transistor to be off during the light-sleep mode and to be on only during a transition period from the light-sleep mode to the active mode.

These and other advantageous features may be better appreciated through the following detailed description.

### BRIEF DESCRIPTION OF THE DRAWINGS

FIG. 1 illustrates a memory bank powered through a first plurality of selectively diode-connected head switch transistors and through a second plurality of head switch transistors that are on only during a transition period from a light-sleep mode to an active mode for the memory in accordance with an aspect of the disclosure.

FIG. 2 illustrates the two pluralities of head switch transistors of FIG. 1 in more detail in accordance with an aspect of the disclosure.

FIG. 3 illustrates a logic circuit for controlling the second plurality of head switch transistors of FIGS. 1 and 2 in accordance with an aspect of the disclosure.

FIG. 4 is a timing diagram for some operating signals of the logic circuit of FIG. 3 in accordance with an aspect of the disclosure.

FIG. 5 is a flowchart of a method of selectively powering a memory through an at least one first head switch transistor and an at least one second head switch transistor in accordance with an aspect of the disclosure.

FIG. 6 illustrates some example mobile devices including a memory in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

A memory typically has several operating modes that correspond to different power supply voltage levels. In a default mode of operation (which is also denoted herein as an active mode), the memory power supply voltage is relatively elevated so that the memory speed is enhanced. Conversely, the memory power supply voltage is discharged in a deep-sleep mode. But in a light-sleep mode, the memory power supply voltage lies between these two extremes. In the light-sleep mode, the memory power supply voltage is sufficient for data retention but is reduced as compared to the default level. In particular, a light-sleep mode as defined herein exists when the bitcells are powered through a diode connection to a power supply node for a memory power supply voltage. As compared to the memory power supply voltage on the power supply node, the resulting bitcell power supply voltage for the bitcells during the light-sleep mode is reduced by a transistor threshold voltage drop due to the diode coupling of the bitcells to the voltage rail. During the active mode, the diode coupling is disabled such that the bitcell power supply voltage substantially equals the memory power supply voltage.

To advantageously switch between the active and light-sleep modes, a selectively diode-connected head switch transistor(s) may be used to provide a light-sleep mode of operation. During the normal mode of operation, the diode connection of the head switch transistors is open circuited. The head switch transistors conduct normally during the active mode such that they pass a bitcell power supply voltage to the memory with essentially no voltage drop. But the diode connection for the head switch transistors is closed during the light-sleep mode, which causes the head switch transistors to introduce a transistor threshold voltage drop in the bitcell power supply voltage as it passes through the head switch transistors to the memory. In a deep-sleep mode, the head switch transistors may be switched off so that the memory is powered down.

With respect to positioning the selectively diode-connected head switch transistors relative to the bitcells, note that the bitcells are arranged into rows and columns. Each row is traversed by a corresponding word line. Similarly, a corresponding pair of bit lines traverse each column. Should all of a memory's bitcells be arranged into one single array, the word line length and the bit line length are increased accordingly. This increased length may cause the bit line capacitance and the word line capacitance to be too high, which slows the memory operating speed. It is thus traditional to split the bitcells into two or more banks, each bank having its own rows and columns of bitcells. In this fashion, the bit line length and the word line length are reduced, thereby allowing faster memory operation. Given this arrangement of the bitcells into banks, the selectively diode-connected head switch transistors may be located adjacent to one end of the columns for a bank.

Since the head switch transistors are at one end of the columns for a bank, the power is distributed to the bitcells in the columns through metal power leads (denoted herein as power rails) that extend parallel to the columns from the head switch transistors. In that regard, the bitcells are formed by transistors on a semiconductor die. The word lines and the bit lines are formed in patterned metal layers that are adjacent to the semiconductor die. Similarly, the power leads for the bitcell power supply voltage are also formed in the patterned metal layers. Since the rows and columns are orthogonal to each other, a bank of bitcells will have a rectangular perimeter having two row-facing sides and two column-facing sides. The bank's columns end at the column-facing sides. It is convenient to locate the head switch transistors adjacent one of the column-facing sides of the bank's rectangular perimeter. In addition to providing power to the columns' bitcells, a bank also needs pre-charging circuitry to precharge the bit lines in each of the columns. Write drivers for write operations and sense amplifiers for read operations also need access to the bit lines. It is thus traditional that the bit line pre-charge circuitry be located adjacent to just one end of the columns (the pre-charge circuitry thus being adjacent to only one of the column-facing sides of the bank's perimeter).

The one-sided positioning of the pre-charging circuitry raises an issue with respect to awakening a memory from the light-sleep mode in that the selectively-diode-connected head switch transistors are also located or positioned adjacent an edge of the bank. Should the head switch transistors be located adjacent to both of the column-facing sides of the bank's perimeter, the bitcells have a relatively stronger power supply voltage as compared to the pre-charging of the bit lines. This imbalance between the bitcell power and the bit line pre-charging power may degrade the bank's write margin. Due to the strength of the bitcell power supply voltage, the write operation may then fail. It is thus traditional that the head switch transistors be located only along one of the column-facing sides of the bank's perimeter. The bitcells adjacent to the remaining column-facing side are then located relatively distant from the head switch transistors. The power rails from the head switch transistors to the bitcells (like any non-superconductor wire or lead) have a resistance that then causes a delay with respect to transitioning a bank from the light-sleep mode back to active mode (the power supply voltage being increased from the lower level used during the light-sleep mode to the default value). It takes time for the bitcell power supply voltage to be sufficient across the columns due to the bitcell power supply voltage being supplied from only one of the column-facing sides. But if head switch transistors are located adjacent to both ends of the column to supply the bitcell power supply voltage, the write margin may be degraded. The resulting delay during the transition from the light-sleep mode to default operation may negatively impact memory speed, particularly for higher speed memories.

To address the wake-up time vs. write margin dilemma, a memory is provided in which head switch transistors are located adjacent to both of the column-facing sides of the bitcell array for a bank. To prevent a degradation of the write margin from the increased strength of the power supply voltage, a memory is disclosed that controls the head switch transistors on one side of the columns to switch on only during a transition period over which the power supply voltage increases from its light-sleep mode level to the default level. When the memory has transitioned to the active mode, the memory switches off the only-on-during-the-transition-period head switch transistors. The bitcell array for a bank is thus powered by two types of head switch transistors that are segregated according to which column-facing side the head switch transistors are located. A plurality of first head switch transistors is maintained on during both the light-sleep mode and during the default mode of operation. These first head switch transistors are located adjacent a first column-facing side of the bank's perimeter. A plurality of second head switch transistors are on only during the transition period and are located adjacent a second column-facing side of the bank's perimeter.

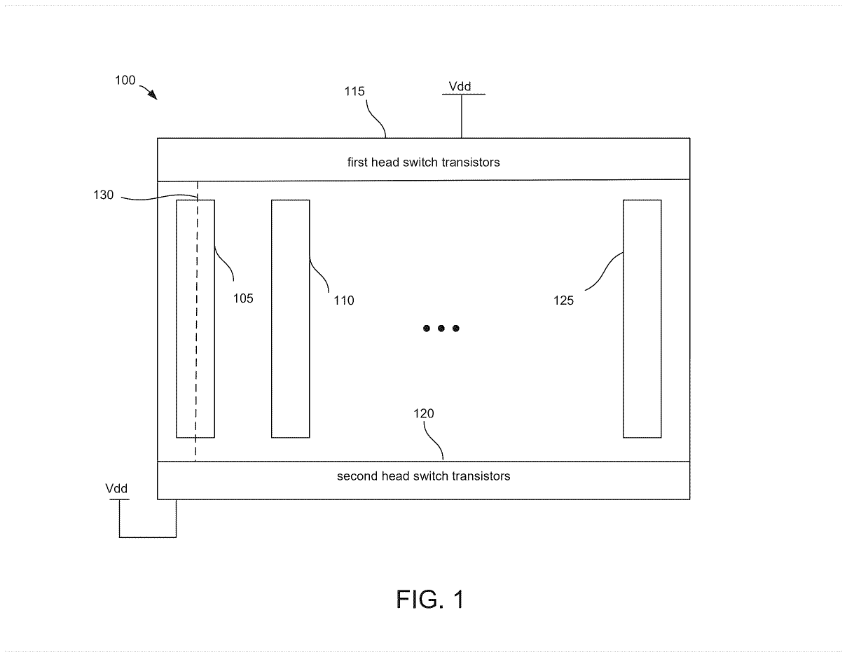

An example bank 100 of bitcells with the two types of head switch transistors is shown in FIG. 1. The bank 100 includes a plurality of columns of bitcells arranged from a first column 105 to a last column 125. For illustration clarity, only the first column 105, a second column 110, and the final column 125 are shown in FIG. 1. Each column of bitcells includes a power rail or lead that traverses the column to provide power to the bitcells. For illustration clarity, a power rail 130 is shown only for the first column 105 in FIG. 1. Each power rail extends from a first plurality of head switch transistors 115 to a second plurality of head switch transistors 120. During the light-sleep mode, a memory controller (not shown in FIG. 1) switches off the second plurality of head switch transistors 120 but selectively diode connects and maintains on the first plurality of head switch transistors 115 as will be explained further herein. A bitcell power supply voltage on the power rails during the light-sleep mode will thus be a transistor threshold voltage lower than a memory power supply voltage powering the first plurality of head switch transistors 115, where the transistor threshold voltage is the threshold voltage for each transistor in the first plurality of head switch transistors.

During the transition period from the light-sleep mode of operation to the active mode, the memory controller switches off the diode connection for the first plurality of head switch transistors 115 and switches on the second plurality of head switch transistors 120. Like the first plurality of head switch transistors 115, the second plurality of head switch transistors 120 is powered by the memory power supply voltage (Vdd). The power rails will thus be powered from both ends with the memory power supply voltage during the transition period from the light-sleep mode to the active mode of operation such that the bitcell power supply voltage will be quickly transitioned to the memory power supply voltage level. When the bitcell power supply voltage on the bitcell power rails has sufficiently transitioned to the memory power supply voltage level, the memory controller switches off the second plurality of head switch transistors 120 while maintaining the first plurality of head switch transistors 115 fully on without any diode connection to transition the bank to the default mode. For example, a read enable or write enable signal may function to trigger a disable signal to switch off the second plurality of head switch transistors 120. During the deep-sleep mode, the memory power supply voltage Vdd may discharged to ground to fully power off the bank 100. Both pluralities 115 and 120 of the head switch transistors are off during the deep-sleep mode.

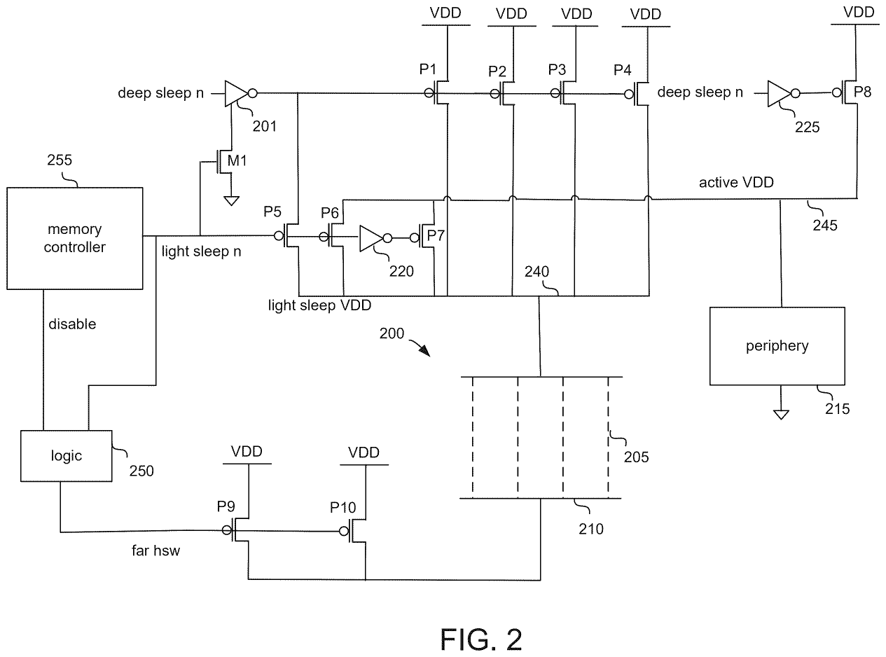

The selective diode connection of the first plurality of head switch transistor is shown in more detail for an example bank 200 in FIG. 2. Bank 200 is a bank of static random-access memory (SRAM) bitcells (not illustrated) although it will be appreciated that other types of memories may also benefit from the selective diode connection disclosed herein. The bitcells in bank 200 are arranged into a plurality of columns with each column traversed by at least one power rail 205. The power rails 205 extend from a first node 240 at a first end of the columns to a second node 210 at a second end of the columns. The first plurality of head switch transistors such as a plurality of type metal-oxide semiconductor (PMOS) head switch transistors P1, P2, P3, and P4 are selectively diode connected during the light-sleep mode to power the power rails through the first node 240. During the active mode, the first plurality of head switch transistors P1, P2, P3, and P4 are fully on without a diode connection.

A source of each of the head switch transistors P1, P2, P3, and P4 couples to a power supply node for the memory power supply voltage (VDD) whereas a drain of each of these head switch transistors couples to the first node 240. During the active mode, the head switch transistors are not diode connected and are fully on. The bitcell array power supply voltage that powers the bank 200 during the active mode is thus virtually equal to the memory power supply voltage during the active mode because the parallel arrangement of the fully switched-on head switch transistors P1 through P4 introduce relatively little voltage loss. Head switch transistors P1 through P4 are each an example of an at least one first head switch transistor having a source coupled to the power supply node and a drain coupled to the first node 240. The bitcell array power supply voltage at the first node 240 may also be denoted as a virtual power supply voltage VDD (virtual VDD) during the active mode since the bitcell power supply voltage is virtually equal to the memory power supply voltage VDD during the active mode.

During a deep-sleep mode, the head switch transistors P1 through P4 are off. To switch these transistors off during the deep-sleep mode, an active-low deep-sleep mode signal (deep sleep n) is asserted by a memory controller 255. As defined herein, a binary signal is deemed to be asserted when the binary signal is logically true, regardless of whether the logical true state is represented with an active-high or an active-low convention. In an active-high convention, a binary signal is asserted by being charged to a power supply voltage and de-asserted by being grounded. Conversely, a binary signal is asserted by being discharged to ground in an active-low convention and de-asserted by being charged to a power supply voltage. Since the deep-sleep mode signal is active low, the deep-sleep mode signal is asserted (having a binary true state) by being discharged to ground. An inverter 201 inverts the deep-sleep mode signal to drive a gate of each of the head switch transistors P1 through P4. An output signal of the inverter 201 is thus charged to the memory power supply voltage during the deep-sleep mode to fully switch off the head switch transistors P1 through P4. The bank 200 is then powered down during the deep-sleep mode and the bitcell array power supply voltage discharged to ground.

A PMOS transistor P5 couples between the gates of the head switch transistors P1 through P4 and the first node 240 to perform the selective diode connection of these head switch transistors. Transistor P5 may thus also be denoted as a diode-connecting transistor or a second transistor. An active-low light-sleep mode signal (light sleep n) drives the gate of transistor P5. Thus, when the light-sleep mode signal is asserted by being discharged to begin the light-sleep mode, the head switch transistors P1 through P4 are diode connected. Each of the head switch transistors P1 through P4 then introduces a transistor threshold voltage drop between the memory power supply voltage VDD and the bitcell power supply voltage at the first node 240. During the light-sleep mode, the bitcell power supply voltage may thus also be denoted as a light-sleep virtual power supply voltage (light sleep VDD). This reduction in the bitcell power supply voltage reduces leakage current losses in the bank 200 during the light-sleep mode. But note that the head switch transistors P1 through P4 were not switched off during the light-sleep mode. In contrast, suppose that the head switch transistors P1 through P4 were switched off during the light-sleep mode and the bank 200 powered through separate diode-connected transistors (not illustrated). As compared to the use of such separate diode-connected transistors, the selective diode connection of the head switch transistors P1 through P4 saves an appreciable amount of switching power that would otherwise be consumed with the switching off and on of the head switch transistors in the transitions between the active and light-sleep modes. Transistor P5 is an example of a second transistor having a source coupled to a gate of the at least one first head switch transistor (head switch transistors P1 through P4) and having a drain coupled to the first node 240.

During the light-sleep mode, the deep-sleep mode signal is de-asserted by being charged to the memory power supply voltage. To prevent inverter 201 from discharging the gates of the head switch transistors P1 through P4 during the light-sleep mode, the light-sleep mode signal drives a gate of an n-type metal-oxide semiconductor (NMOS) transistor M1 that couples between a ground node of the inverter 201 and ground. With the light-sleep mode signal asserted by being discharged to ground, transistor M1 is switched off to float inverter 201 with respect to ground and thus prevent inverter 201 from grounding the gates of the head switch transistors P1 through P4 during the light-sleep mode.

A memory periphery 215 includes memory elements such as row and column decoders, sense amplifiers, write drivers, column multiplexers to form the read and write paths to the bitcell array in the bank 200. The periphery 215 receives a memory periphery power supply voltage through a power supply node 245 that couples to a drain of a PMOS head switch transistor P8. Transistor P8 may also be denoted herein as a third transistor. A source of the head switch transistor P8 couples to the memory power supply voltage rail. An inverter 225 inverts the deep-sleep mode signal to control the gate of the head switch transistor P8. During the deep-sleep mode, the head switch transistor P8 switches off due to the inversion of the deep-sleep mode signal to cause the memory periphery 215 to power down. During the active mode (and also the light-sleep mode), the head switch transistor P8 is fully on such that the memory periphery power supply voltage is virtually equal to the memory power supply voltage VDD. The memory periphery power supply voltage may thus also be denoted as a virtual VDD or active VDD during the active and light-sleep modes. Note that in this implementation, the memory periphery 215 does not practice the light-sleep mode. However, in alternative implementations, head switch transistor P8 may be selectively diode connected analogously as discussed for the head switch transistors P1 through P4 such that the memory periphery 215 may also have a light-sleep mode. In other alternative implementations, the head switch transistor P8 may be replaced by a plurality of head switch transistors arranged in parallel as discussed for head switch transistors P1 through P4.

The transistor threshold voltage drop in the bitcell power supply voltage introduced by the switching on of transistor P5 may cause a delay in the transition from the light-sleep mode to the active mode. In that regard, the first node 240 may have an appreciable amount of capacitance, which affects the voltage charging time. With the bitcell array power supply voltage being lower than the memory power supply voltage by a full transistor threshold voltage drop, there may be too much delay required to transition the bank 200 from the light-sleep mode to the active mode. To slightly increase the bitcell array power supply voltage above a transistor threshold voltage drop from the memory power supply voltage during the light-sleep mode to reduce the transition time, a PMOS transistor P6 may have its source coupled to the first node 240 and a drain coupled to the power supply node 245. The light-sleep mode signal drives a gate of transistor P6 such that transistor P6 is on during the light-sleep mode and is off during the active and deep-sleep modes. Transistor P6 is relatively small compared to the head switch transistors P1 through P4. Recall that the power supply node 245 is charged to the virtual VDD during the light-sleep mode (and also during the active mode). Due to the relatively small size of transistor P6, it cannot charge the first node 240 to the virtual VDD during the light-sleep mode despite being fully on. Thus, the bitcell array power supply voltage during the light-sleep mode is slightly increased with respect to the threshold voltage drop from the memory power supply voltage that would otherwise exist if just transistor P5 were on without the presence of transistor P6. Since the bitcell array power supply voltage is thus only slightly increased from transistor P6 being on, leakage currents are still advantageously reduced during the light-sleep mode yet the transition delay from the light-sleep mode to the active mode may also be reduced.

To further reduce the transition time from the light-sleep mode back to the active mode, an inverter 220 may invert the light-sleep mode signal to drive a gate of a PMOS transistor P7 that couples in parallel with transistor P6 between the power supply node 245 and the first node 240. Transistor P7 is thus off during the light-sleep mode and on during the active mode. The virtual VDD at the power supply node 245 may then conduct through transistor P7 at the initiation of the active mode from the light-sleep mode to charge the first node 240 more quickly towards the memory power supply voltage.

A PMOS transistor P9 and P10 are an example of the second plurality of head switch transistors. It will be appreciated that more than two (or just a single) second head switch transistors may be used in alternative implementations. Second head switch transistors P9 and P10 each has a source coupled to the power supply node for the memory power supply voltage Vdd and a drain coupled to the second node 210 at the second end of the bitcell power rails 205. To control the on/off state of the head switch transistors P9 and P10, a logic circuit 250 processes the active-low sleep signal (light sleep n) and the disable signal to provide a control signal (far hsw) that drives the gates of the head switch transistors P9 and P10. In that regard, the second plurality of head switch transistors may also be denoted as the far head switch (hsw) transistors.

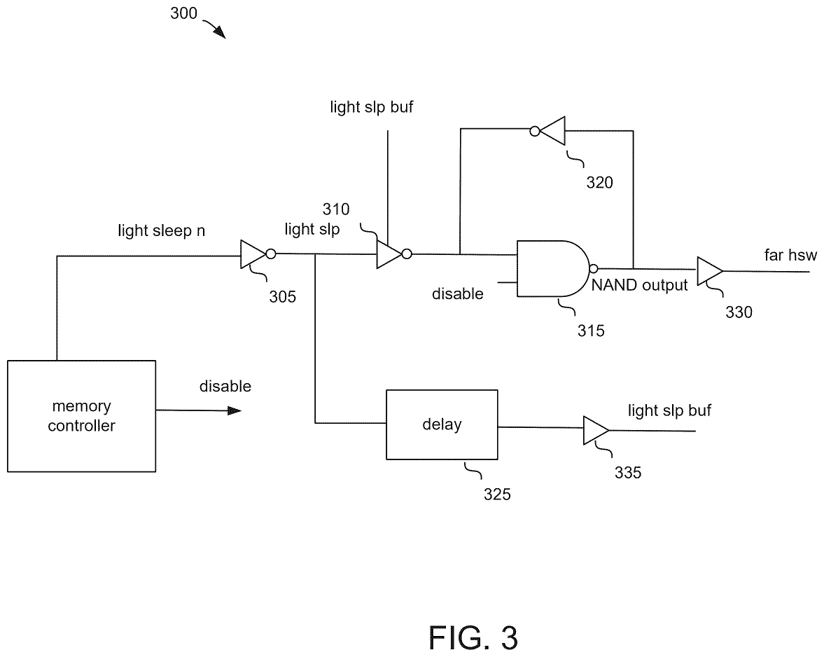

An example implementation 300 of the logic circuit 250 is shown in FIG. 3. An inverter 305 inverts the active-low light sleep signal (light sleep n) to produce a second light sleep signal (light slp). The active-low light sleep signal may thus also be denoted as a first light sleep signal. At the transition from the light-sleep mode to the active mode, the second light sleep signal will thus transition from the memory power supply voltage to ground. An inverter 310 inverts the second light sleep signal to drive a first input terminal of a logic gate such as a NAND gate 315. The disable signal from the memory controller 255 (FIG. 2) drives a second input terminal of the NAND gate 315. The memory controller 255 pulses the disable signal low such as in response to an assertion of a write enable signal (or a read enable signal). During the transition from the light-sleep mode to the active mode, the memory controller 255 maintains a voltage of disable signal to the memory power supply voltage such that an output signal (NAND output) of the NAND gate 315 is a logical one. An inverter 320 inverts the output signal from the NAND gate 315 to drive the first input terminal of the NAND gate 315 to latch the output signal. A buffer 330 buffers the output signal to produce the far head switch control signal (far hsw).

A delay circuit 325 delays the second light sleep signal to drive a buffer 335 to produce a light sleep buffer signal (light slp buf). The light sleep buffer signal functions as a power supply voltage to the inverter 310. The inverter 310 will thus lose its power supply voltage after the delay through the delay circuit 325 (and the processing delay through the buffer 335) in response to the grounding of the second light sleep signal light slp. The output signal from the inverter 310 will thus float when the light sleep buffer signal is grounded.

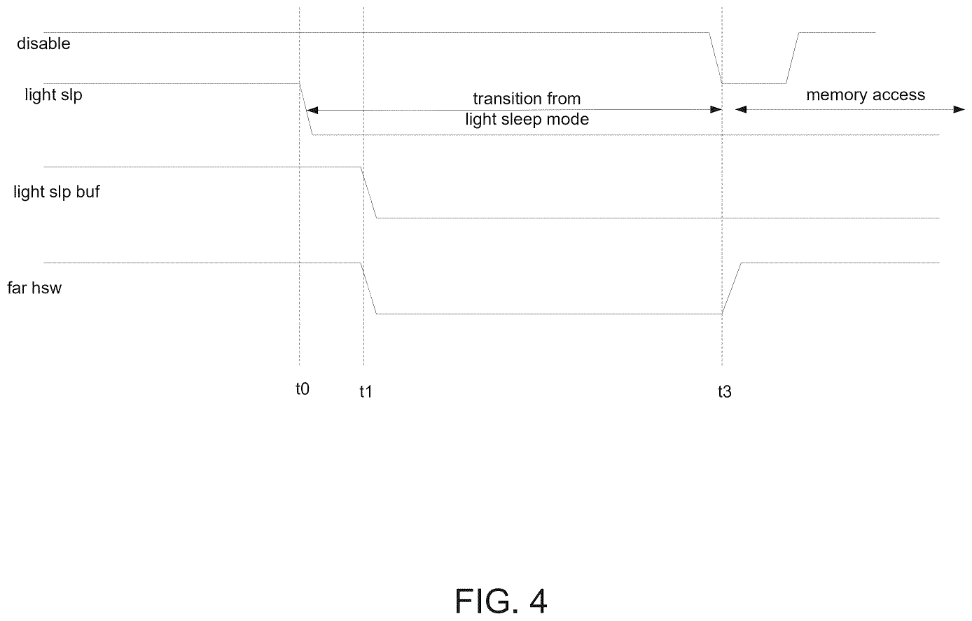

A timing diagram for the implementation 300 is shown in FIG. 4. At a time t0, the transition period from the light-sleep mode to the active mode begins with the discharging of the second light sleep signal (light slp). The disable signal is maintained high (charged to the power supply voltage) prior to and during the transition period. The transition low of the second light sleep signal causes the control signal (far hsw) for the second plurality of head switch transistors to discharge at a time t1 to switch on the second plurality of head switch transistors (e.g., head switch transistors P9 and P10). At time t1, the light sleep buffer signal (light slp buf) also discharges to switch off the inverter 310 (FIG. 3). The disable signal is then pulsed low at a time t3 such as in reaction to an assertion of a read enable signal or a write enable signal to end the transition period to cause the control signal (far hsw) to be charged to the power supply voltage and switch off the second plurality of head switch transistors. The transition period from the light-sleep mode to the active mode thus extends from time t1 to the time t3. A read or write operation (memory access) then occurs after time t3.

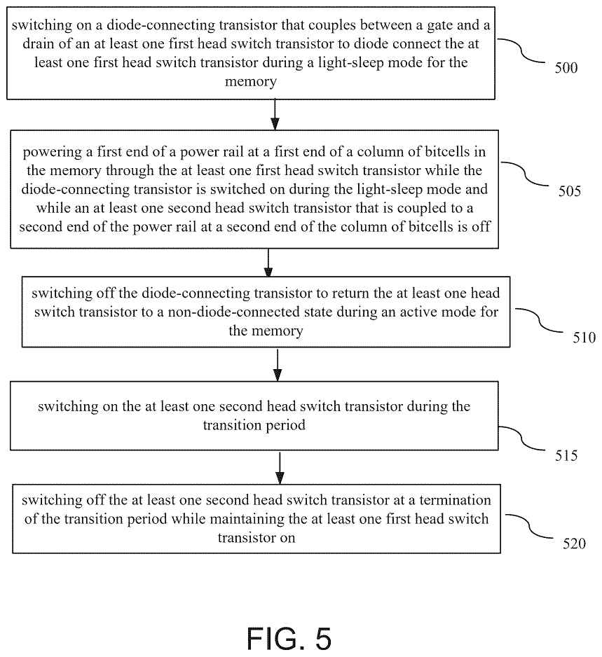

A method of powering a memory through two pluralities of head switch transistors will now be discussed with reference to the flowchart of FIG. 5. The method includes an act 500 switching on a diode-connecting transistor that couples between a gate and a drain of an at least one first head switch transistor to diode connect the at least one first head switch transistor during a light-sleep mode for the memory. The switching on of transistor P5 as discussed with regard to FIG. 2 is an example of act 500. The method also includes an act 505 of powering a first end of a power rail at a first end of a column of bitcells in the memory through the at least one first head switch transistor while the diode-connecting transistor is switched on during the light-sleep mode and while an at least one second head switch transistor that is coupled to a second end of the power rail at a second end of the column of bitcells is off. The powering of the node 240 through the head switch transistor P1-P4 while the head switch transistors P9 and P10 are off is an example of act 505. In addition, the method includes an act 510 of switching off the diode-connecting transistor to return the at least one first head switch transistor to a non-diode-connected state during a transition period from the light-sleep mode to an active mode for the memory. The switching off of the transistor P5 is an example of act 510. The method further includes an act 515 of switching on the at least one second head switch transistor during the transition period. The switching on of the head switch transistors P9 and P10 during the transition period as discussed with respect to FIGS. 2-4 is an example of act 515. Finally, the method includes an act 520 of switching off the at least one second head switch transistor at a termination of the transition period while maintaining the at least one first head switch transistor on. The switching off of the head switch transistors P9 and P10 while the head switch transistors P1-P4 are on at the termination of the transition period is an example of act 520.

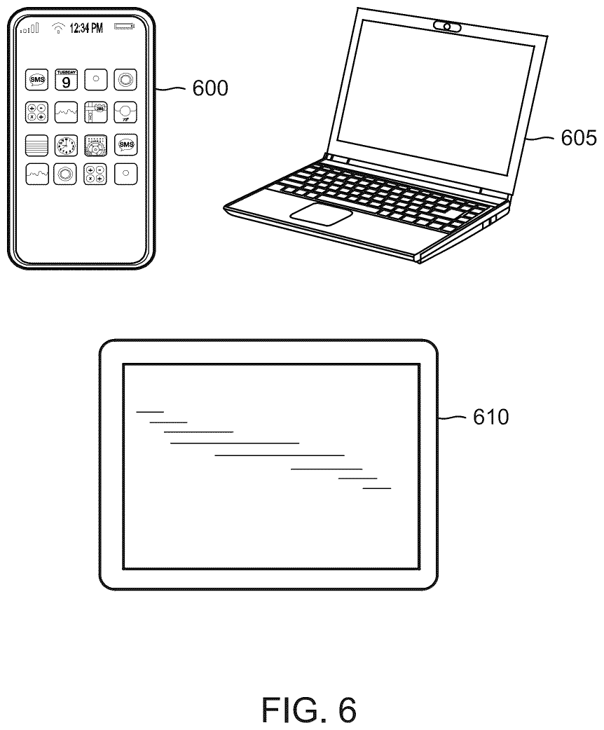

A memory having the first and second plurality of head switch transistors as disclosed herein may be advantageously included in a variety of electronic systems. For example, as shown in FIG. 6, a cellular telephone 600, a laptop computer 605, and a tablet PC 610 may all include a memory having the two pluralities of head switch transistors in accordance with the disclosure. Other exemplary electronic systems such as a music player, a video player, a communication device, and a personal computer may also be configured with a memory in accordance with the disclosure.

The disclosure will now be summarized in the following series of clauses:
Clause 1. A memory, comprising:
   a plurality of bitcells arranged into a plurality of columns, each column being traversed by at least one power rail extending from a first node at a first end of the column to a second node at a second end of the column;
   a power supply node for a memory power supply voltage;
   an at least one first head switch transistor having a first terminal coupled to the power supply node and a second terminal coupled to the first node;
   a second transistor having a first terminal coupled to a gate of the at least one first head switch transistor and having a second terminal coupled to the first node; and
   an at least one second head switch transistor having a first terminal coupled to the power supply node and a second terminal coupled to the second node.
Clause 2. The memory of clause 1, further comprising:
   a logic circuit;
   a node for a first light-sleep mode signal coupled to a gate of the second transistor and to an input terminal of the logic circuit, wherein the logic circuit is configured to process the first light-sleep mode signal to produce a control signal at the gate of the at least one second head switch transistor.
Clause 3. The memory of clause 2, further comprising:
   a memory controller configured to produce the first light-sleep mode signal and to produce a disable signal, and wherein the logic circuit is configured to respond to the disable signal to charge a second light-sleep mode signal to a memory power supply voltage.
Clause 4. The memory of any of clauses 1-3, wherein the at least one first head switch transistor comprises a first plurality of p-type metal-oxide semiconductor (PMOS) transistor, and wherein the at least one second head switch transistor comprises a second plurality of head switch transistors.
Clause 5. The memory of clause 4, wherein the second transistor comprises a PMOS transistor.
Clause 6. The memory of any of clauses 1-5, further comprising:
   a memory periphery having an input node for receiving a memory periphery power supply voltage; and
   a third transistor having a first terminal coupled to the power supply node and having a second terminal coupled to the input node.
Clause 7. The memory of clause 6, wherein the first terminal of the third transistor is a source and the second terminal of the third transistor is a drain, and wherein the third transistor is a PMOS transistor.
Clause 8. The memory of clause 3, wherein the logic circuit comprises:
   a first inverter configured to invert the first light-sleep mode signal to produce the second light-sleep mode signal;
   a second inverter configured to invert the second light-sleep signal;
   a logic gate configured to process an output signal of the second inverter and the disable signal to provide a logic gate output signal; and
   a buffer configured to buffer the logic gate output signal to produce the control signal.
Clause 9. The memory of clause 8, wherein the logic circuit further comprises:
   a third inverter coupled between an output terminal of the logic gate and an output terminal of the second inverter, and wherein the logic gate comprises a NAND gate.
Clause 10. The memory of clause 8, wherein the logic circuit further comprises:
   a delay circuit configured to delay the second light-sleep mode signal into a delayed signal; and
   a buffer configured to buffer the delayed signal to provide a buffered signal, wherein the second inverter is powered by the buffered signal.
Clause 11. The memory of any of clauses 1-10, wherein the memory is included within a cellular telephone.
Clause 12. A method of powering a memory, comprising:
   switching on a diode-connecting transistor that couples between a gate and a drain of an at least one first head switch transistor to diode connect the at least one first head switch transistor during a light-sleep mode for the memory;
   powering a first end of a power rail at a first end of a column of bitcells in the memory through the at least one first head switch transistor while the diode-connecting transistor is switched on during the light-sleep mode for the circuit and while an at least one second head switch transistor that is coupled to a second end of the power rail at a second end of the column of bitcells is off;
   switching off the diode-connecting transistor to return the at least one first head switch transistor to a non-diode-connected state during a transition period from the light-sleep mode to an active mode for the memory;
   switching on the at least one second head switch transistor during the transition period; and
   switching off the at least one second head switch transistor at a termination of the transition period while maintaining the at least one first head switch transistor on.
Clause 13. The method of clause 12, further comprising:
   switching off the at least one first head switch transistor and the at least one second head switch transistor during a deep-sleep mode for the memory.
Clause 14. The method of any of clauses 12-13, further comprising:
   pulsing a disable signal responsive to a beginning of a read or write operation to the memory, wherein the termination of the transition period is responsive to the pulsing of the disable signal.
Clause 15. The method of clause 14, wherein the pulsing of the disable signal comprises discharging the disable signal for a pulsing period.
Clause 16. A memory, comprising:
   a power supply node for a memory power supply voltage;
   a column of bitcells;
   a power rail extending from a first end of the power rail at a first end of the column of bitcells to a second end of the power rail at a second end of the column of bitcells;
   an at least one first head switch transistor coupled between the power supply node and the first end of the power rail;
   an at least one second head switch transistor coupled between the power supply node and the second end of the power rail; and
   a memory controller configured to control the at least one first head switch transistor to be diode-connected state during a light-sleep mode for the memory and to be in a non-diode-connected state during an active mode for the memory, wherein the memory controller is further configured to control the at least one second head switch transistor to be off during the light-sleep mode and to be on only during a transition period from the light-sleep mode to the active mode.
Clause 17. The memory of clause 16, further comprising:
   a first node for a deep-sleep mode signal; and
   a switch coupled between the first node for the deep-sleep mode signal and a gate of the at least one first head switch transistor.
Clause 18. The memory of clause 17, wherein the switch is configured to open during the light-sleep mode and to close during a deep-sleep mode for the memory and during the active mode for the memory.
Clause 19. The memory of any of clauses 17-18, further comprising:
   a first inverter having an input terminal coupled to a second node for a deep-sleep mode input signal and having an output terminal coupled to the first node for the deep-sleep mode signal.
Clause 20. The memory of any of clauses 16-19, wherein the column of bitcells comprises a column of static random-access memory (SRAM) bitcells.

It will be appreciated that many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. A memory, comprising:
a plurality of bitcells arranged into a plurality of columns, each column being traversed by at least one power rail extending from a first node at a first end of the column to a second node at a second end of the column;
a power supply node for a memory power supply voltage;
an at least one first head switch transistor having a first terminal coupled to the power supply node and a second terminal coupled to the first node;
a second transistor having a first terminal coupled to a gate of the at least one first head switch transistor and having a second terminal coupled to the first node; and
an at least one second head switch transistor having a first terminal coupled to the power supply node and a second terminal coupled to the second node.

2. The memory of claim 1, further comprising:
a logic circuit; and
a node for a first light-sleep mode signal coupled to a gate of the second transistor and to an input terminal of the logic circuit, wherein the logic circuit is configured to process the first light-sleep mode signal to produce a control signal at the gate of the at least one second head switch transistor.

3. The memory of claim 2, further comprising:
a memory controller configured to provide the first light-sleep mode signal and to provide a disable signal, and wherein the logic circuit is configured to respond to the disable signal to charge a second light-sleep mode signal to a memory power supply voltage.

4. The memory of claim 1, wherein the at least one first head switch transistor comprises a first plurality of p-type metal-oxide semiconductor (PMOS) transistor, and wherein the at least one second head switch transistor comprises a second plurality of head switch transistors.

5. The memory of claim 4, wherein the second transistor comprises a PMOS transistor.

6. The memory of claim 1, further comprising:
a memory periphery having an input node for receiving a memory periphery power supply voltage; and
a third transistor having a first terminal coupled to the power supply node and having a second terminal coupled to the input node.

7. The memory of claim 6, wherein the first terminal of the third transistor is a source and the second terminal of the third transistor is a drain, and wherein the third transistor is a PMOS transistor.

8. The memory of claim 3, wherein the logic circuit comprises:
a first inverter configured to invert the first light-sleep mode signal to produce the second light-sleep mode signal;
a second inverter configured to invert the second light-sleep mode signal;
a logic gate configured to process an output signal of the second inverter and the disable signal to provide a logic gate output signal; and
a buffer configured to buffer the logic gate output signal to produce the control signal.

9. The memory of claim 8, wherein the logic circuit further comprises:
a third inverter coupled between an output terminal of the logic gate and an output terminal of the second inverter, and wherein the logic gate comprises a NAND gate.

10. The memory of claim 9, wherein the logic circuit further comprises:
a delay circuit configured to delay the second light-sleep mode signal to provide a delayed signal; and
a buffer configured to buffer the delayed signal to provide a buffered signal, wherein the second inverter is powered by the buffered signal.

11. The memory of claim 1, wherein the memory is included within a cellular telephone.

12. A method of powering a memory, comprising:
switching on a diode-connecting transistor that couples between a gate and a drain of an at least one first head switch transistor to diode connect the at least one first head switch transistor during a light-sleep mode for the memory;
powering a first end of a power rail at a first end of a column of bitcells in the memory through the at least one first head switch transistor while the diode-connecting transistor is switched on during the light-sleep mode and while an at least one second head switch transistor that is coupled to a second end of the power rail at a second end of the column of bitcells is off;
switching off the diode-connecting transistor to return the at least one first head switch transistor to a non-diode-connected state during a transition period from the light-sleep mode to an active mode for the memory;
switching on the at least one second head switch transistor during the transition period; and
switching off the at least one second head switch transistor at a termination of the transition period while maintaining the at least one first head switch transistor on.

13. The method of claim 12, further comprising:
switching off the at least one first head switch transistor and the at least one second head switch transistor during a deep-sleep mode for the memory.

14. The method of any of claim 12, further comprising:
pulsing a disable signal responsive to a beginning of a read or write operation to the memory, wherein the termination of the transition period is responsive to the pulsing of the disable signal.

15. The method of claim 14, wherein the pulsing of the disable signal comprises discharging the disable signal for a pulsing period.

16. A memory, comprising:
a power supply node for a memory power supply voltage;
a column of bitcells;
a power rail extending from a first end of the power rail at a first end of the column of bitcells to a second end of the power rail at a second end of the column of bitcells;
an at least one first head switch transistor coupled between the power supply node and the first end of the power rail;
an at least one second head switch transistor coupled between the power supply node and the second end of the power rail; and
a memory controller configured to control the at least one first head switch transistor to be diode-connected state during a light-sleep mode for the memory and to be in a non-diode-connected state during an active mode for the memory, wherein the memory controller is further configured to control the at least one second head switch transistor to be off during the light-sleep mode and to be on only during a transition period from the light-sleep mode to the active mode.

17. The memory of claim 16, further comprising:
a first node for a deep-sleep mode signal; and
a switch coupled between the first node for the deep-sleep mode signal and a gate of the at least one first head switch transistor.

18. The memory of claim 17, wherein the switch is configured to open during the light-sleep mode and to close during a deep-sleep mode for the memory and during the active mode for the memory.

19. The memory of claim 17, further comprising:
a first inverter having an input terminal coupled to a second node for a deep-sleep mode input signal and having an output terminal coupled to the first node for the deep-sleep mode signal.

20. The memory of claim 16, wherein the column of bitcells comprises a column of static random-access memory (SRAM) bitcells.
